(19) United States
(12) Patent Application Publication
(10) Pub. No.: US 2014/0360757 A1
(43) Pub. Date: Dec. 11, 2014

(54) TRANSPARENT CONDUCTIVE FILM HAVING ANISOTROPIC ELECTRICAL CONDUCTIVITY

(71) Applicant: NANCHANG O-FILM TECH. CO. LTD., JIANGXI (CN)

(72) Inventors: Yulong Gao, Jiangxi (CN); Zheng Cui, Jiangsu (CN); Chao Sun, Jiangxi (CN)

(73) Assignee: NANCHANG O-FILM TECH. CO., LTD., JIANGXI 330013 (CN)

(21) Appl. No.: 13/985,738

(22) PCT Filed: Dec. 20, 2012
(86) PCT No.: PCT/CN2012/087080

§ 371 Date: Aug. 15, 2013

(30) Foreign Application Priority Data
Oct. 25, 2012 (CN) 201210413401.0

(51) Int. Cl. H05K 1/02

(52) U.S. Cl. CPC H05K 1/0274; H05K 1/0298; H05K 2201/0338
USPC 174/250

(57) ABSTRACT

A transparent conductive film module is provided which includes a first transparent conductive film and a second transparent conductive film, which are transparent conductive films with metal embedded grids and have grid-like grooves evenly filled with conductive material. The slope of the grid metal lines in the first transparent conductive film has greater probability density in a lateral direction than that in a vertical direction; slope of the grid metal lines in the second transparent conductive film has greater probability density in a vertical direction than in a lateral direction. This transparent conductive film module can ensure constant electrical conductivity while having an increased light transmittance

### FIELD OF THE INVENTION

The present disclosure relates to the field of the transparent conductive film, and specifically to a transparent conductive film having anisotropic electrical conductivity.

### BACKGROUND OF THE INVENTION

The transparent conductive film is a film having good electrical conductivity, and a high visible light transmittance. The transparent conductive film has been widely used in flat panel displays, photovoltaic devices, touch panels and electromagnetic shielding, and other fields, having a very broad market space.

ITO has dominated the market of the transparent conductive film. However, in most practical applications such as a touchscreen, the transparent conductive film often needs to be patterned through exposure, development, etching, cleaning, and other procedures, i.e. a fixed conductive region and an insulating region are formed on the surface of the substrate based on the graphic design. In comparison, forming a metal grid directly on a specified region of the substrate by means of the printing method can eliminate the need for the patterning process, and has such advantages as low pollution and low cost.

The application of cell phones is becoming widespread with the development of technology, and now touchscreen phones occupy a large market share in the entire cell phone market. The touchscreen technology mainly includes a resistive touchscreen, a capacitive touchscreen and so on. Under the premise of ensuring electrical conductivity, their light transmittances are not satisfactory, just up to around 80%. The touchscreen is inevitably required to have a higher light transmittance for the overall brightness and color fidelity of the touchscreen.

In the existing cell phone touchscreen, in order to reduce the thickness and weight of the cell phone, a flexible partterned transparent conductive film is mostly used. A general touchscreen needs two pieces of the transparent conductive film to compose an upper electrode and a lower electrode to achieve the touch function. However, when the two pieces of the transparent conductive film are combined to each other, the light transmittance is bound to be further reduced. It is well known that the light transmittance of the patterned transparent conductive film is related to the area of the grid and the width of the metal wire, i.e. the greater the area of the grid, and the less the width of the metal wire are, the higher the transmittance is. While the area of the grid and the width of the metal wire are likewise an important factor influencing the electrical conductivity, i.e. the less the area of the grid, and the greater the width of the metal wire are, the higher the electrical conductivity is. Therefore, there is confliction and constraint between these two performance parameters of transmittance and conductivity.

Japanese companies, Dai Nippon Printing, Fuji Film and Gunze, German company, PolyIC, and the American company, Atmel all use the printing method to obtain the patterned transparent conductive film having excellent properties. The grid metal line obtained by PolyIC has a line width of 15 μm and a surface sheet resistance of 0.4-1 Ω/sq, but a light transmittance only greater than 80%. The grid metal line obtained by Atmel has a line width of 5 μm and a surface sheet resistance of 10 Ω/sq, but a light transmittance of only greater than 86%.

Transparent conductive films based on the embedded patterned metal grid, PET or a transparent conductive film on a glass substrate all have a sheet resistance less than 10 Ω/sq, and a line width of the metal line less than 3 μm, but the light transmittance of the transparent conductive film on the PET substrate is greater than 85%, while the light transmittance of the transparent conductive film on the glass substrate is greater than 85%.

In summary, in order to meet the need of development, improving the light transmittance of the visible light based on the same electrical conductivity has become a problem to be urgently solved.

### SUMMARY OF THE INVENTION

In view of this, the purpose of the present disclosure is to provide a transparent conductive film having anisotropic electrical conductivity, wherein the first transparent conductive film and the second transparent conductive film included in this transparent conductive film module can keep the original electrical conductivity while improving the light transmittance.

A transparent conductive film module, includes: a first transparent conductive film and a second transparent conductive film, which are transparent conductive films with metal embedded grids and have grid-like grooves evenly filled with conductive material. Wherein slope of the grid metal lines in the first transparent conductive film has greater probability density in a lateral direction than that in a vertical direction and slope of the grid metal lines in the second transparent conductive film has greater -probability density in a vertical direction than that in a vertical direction.

Preferably, the probability density of the grid metal lines of the first transparent conductive film with slope ranged in a range of (−1, 1) is greater than that of the grid metal lines with the slope ranged in other ranges. The probability density of the grid metal lines of the second transparent conductive film with slope ranged in ranges of (−∞, −1) and (1, +∞) is greater than that of the grid metal lines with the slope ranged in other ranges.

Preferably, the first transparent conductive film is laminated to the second transparent conductive film up and down.

Preferably, the first transparent conductive film and the second transparent conductive film shares one and the same substrate, and the first transparent conductive film and the second transparent conductive film are attached to front and back sides of the substrate, respectively.

A transparent conductive film, includes: metal embedded grids, which are formed by filling grid-like grooves defined therein with conductive material, wherein slope of the grid metal lines in the transparent conductive film has greater probability density in one of two orthogonal directions than that in the other direction.

The present disclosure, through stretching and intercepting the grid in the first transparent conductive film and the second transparent conductive film in the transparent conductive film module in the X and Y directions, respectively, ensures increase in the area of the grid, i.e. the light transmitting region, thus making the light transmittance of the entire transparent conductive film increased. Meanwhile, because stretching and intercepting in a single direction can ensure the distribution density and length of the metal line contributing to the electrical conductivity in this direction is essentially constant, the electrical conductivity of this transparent conductive film can be kept constant.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a structural schematic view of an existing transparent conductive film;

FIGS. 2A-2C are schematic views of the conductive film module in the existing touchscreen;

FIGS. 3A-3B are schematic views of the transparent conductive film module of the first example of the present disclosure;

FIG. 4 is a flow chart of the manufacture of the transparent conductive film in FIG. 3A;

FIG. 5 is a flow chart of the manufacture of the transparent conductive film in FIG. 3B;

FIGS. 6A-6B are schematic views of the transparent conductive film module of the second embodiment of the present disclosure;

FIGS. 7A-7B correspond to an artwork of manufacture of the transparent conductive film in FIGS. 6A-6B, respectively;

FIG. 8 is a schematic view of the transparent conductive film module of the third embodiment of the present disclosure;

FIG. 9 is a stereoscopic view of the transparent conductive film module in the third embodiment;

FIG. 10 is a stereoscopic view of the transparent conductive film module of the fourth embodiment of the present disclosure; and

FIGS. 11A-11B are schematic views of the transparent conductive film of the fourth embodiment.

### DETAILED DESCRIPTION

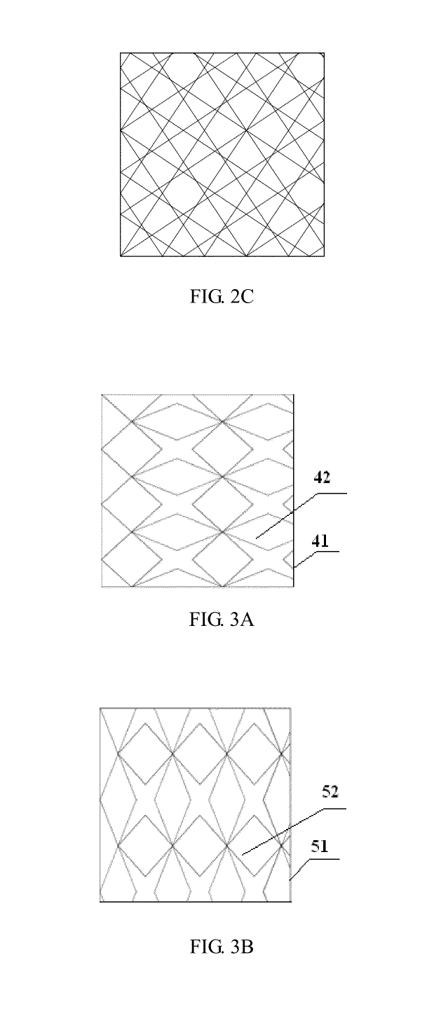

FIGS. 2A-2C are schematic views of the conductive film module of a conventional touchscreen. As shown in the FIGS, grids 22 and 32 in transparent conductive films 21 and 31 are rhombus-shaped, and the rhombus grids 22 and 32 of the transparent conductive films 21 and 31 are arranged complementarily and distributed evenly in the entire transparent conductive film. The visible light transmittance of the transparent conductive films 21 or 31 is greater than 82.7%. However, to be used in the touchscreen, the transparent conductive films 21 and 31 need to be overlapped. After overlapping, the light transmitting portion of the transparent conductive film module is further reduced, making a light transmittance of the two overlapped layers of the transparent conductive films 21 and 31 here be as low as 81.3%. In this case, for improving the light transmittance, the distribution density of the grids 22 and 32 has to be reduced, i.e. increasing the area of the grid and reducing the amount of the grid lines. The transparent conductive film obtained by this method has an increased light transmittance. However, due to the amount of the grid lines of any of the transparent conductive films 21 and 31 in the X and Y directions being reduced, the electrical conductivity of these two transparent conductive films is reduced. There is a contradiction between the two parameters, light transmittance and electrical conductivity.

In order to solve the above problem, on the consideration that two layers of the conductive film of the touchscreen combined to each other are both required to be unidirectionally electrical conductive , the present disclosure proposes a transparent conductive film. In a single piece of the transparent conductive film, under the premise that the distribution density of the grid metal lines with a slope closer to the X or Y direction is constant, the area of the grid of each of the transparent conductive films is increased. Therefore, the transparent conductive film module including two overlapped transparent conductive films combined to each other is improved in light transmittance as well as having constant electrical conductivity.

The technical solution in the examples of the present disclosure will be described clearly and completely with reference to the views of the examples of the present disclosure. Obviously, the examples as described are only part rather than all of the examples of the present disclosure. All other examples obtained by those of ordinary skill in the art according to the examples of the present disclosure without making any inventive effort all fall within the scope of protection of the present disclosure.

### EXAMPLE 1

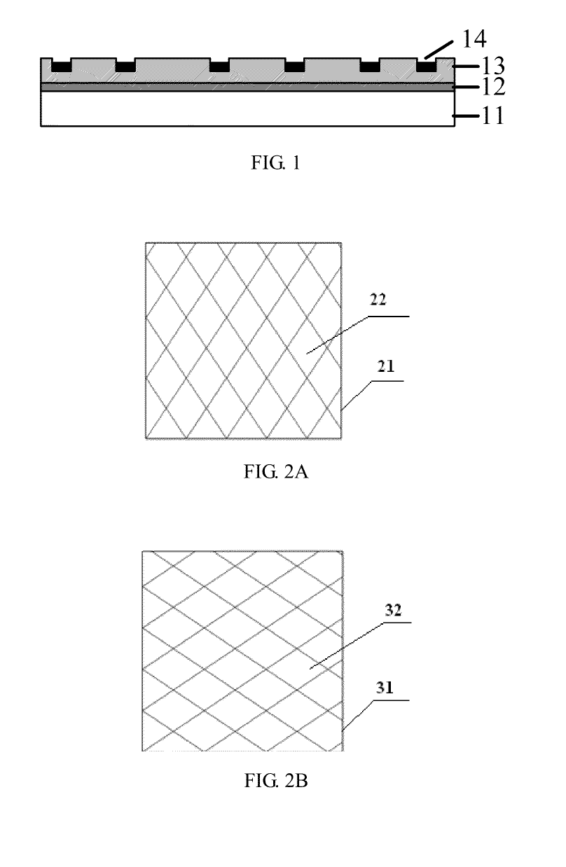

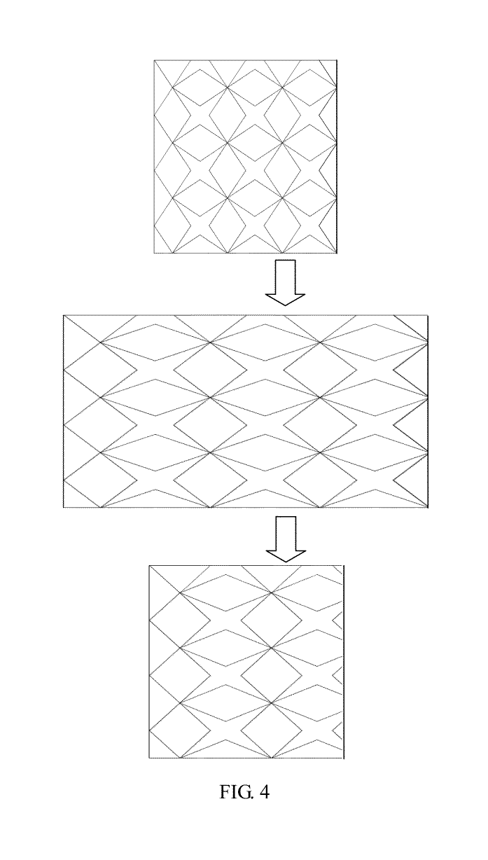

FIGS. 3A-3B are schematic views of the transparent conductive film module of the first example of the present disclosure. This transparent conductive film module includes a first transparent conductive film 41 and a second transparent conductive film 51, both of which are the metal embedded transparent conductive film. As shown in FIG. 1, the transparent conductive film includes the following components from bottom to top: the PET substrate 11 having a thickness of 188 μm; the acrylic UV adhesive 13 defining grid-shaped grooves, with a depth of 3 μm and a width of 2.2 μm; the grooves are filled with the metal silver 14 having a thickness of about 2 μm, less than the depth of the grooves. Nano silver ink is filled into the grooves trench by scrape coating and sintered. The silver ink has a solid content of 35%, and a sintering temperature of 150° C. A tackifier layer 12 is further arranged between the UV adhesive 13 and the substrate 11, so as to increase the bonding strength between the UV adhesive 13 and the substrate 11.

As shown in FIG. 3A, the grids 42 of the transparent conductive film 41 are rhombus grids comprising metal lines, wherein the slopes of the metal lines of the grids 42 of the transparent conductive film 41 have a greater distribution probability density in a lateral direction than that in a vertical direction, that is, the amount of the metal lines having a slope close to the X axis is greater than that of the metal lines having a slope close to the Y axis. The visible light transmittance of the transparent conductive film 14 is greater than 83.6%. As shown in FIG. 3B, the grids 52 of the transparent conductive film 51 are rhombus grids composed of metal lines, wherein the slopes of the metal lines of the grid 52 of the transparent conductive film 51 have a greater distribution probability density in a lateral direction than that in a vertical direction, that is, the amount of the metal lines having a slope close to the Y axis direction is greater than that of the metal lines having a slope close to the X axis direction. The visible light transmittance of the transparent conductive film 51 is greater than 83.6%. The visible light transmittance of the overlapped module with the two transparent conductive films 41 and 51 is greater than 82.4%. Compared with the overlapped module of the transparent conductive film in FIG. 2C, the light transmittance of present embodiment is higher than that of the existing transparent conductive film module.

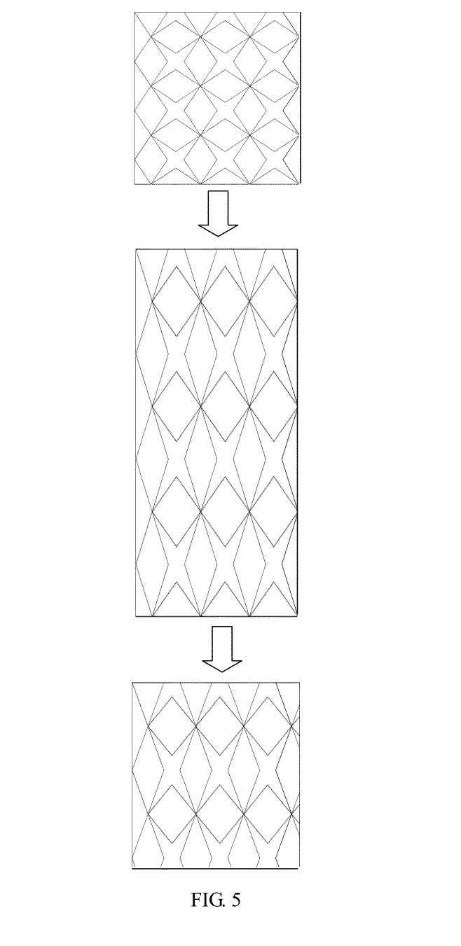

FIGS. 4 and 5 show the design procedure of the grids two transparent conductive film in FIGS. 3A-3B. As shown in the FIGS, to work out the grids in FIG. 3A, evenly distributed rhombus grids are drawn on the surface, then the grids are stretched in the X direction so as to elongate the grids in the X direction by 100%, and half stretched grids are intercepting off in the X direction, to obtain the grids of the transparent conductive film as shown in FIG. 3A. Because these grids are obtained by stretching the original grids in the X direction, grids distribution density of the transparent conductive film is reduced in the X direction. Area of the grids are increased, therefore, light transmittance of the transparent conductive film is improved. Additionally, the slope of the grid metal lines is close to the X direction, i.e. the distribution density of the metal lines contributing to the electrical conductivity in the X direction is kept constant, and thus the electrical conductivity of the transparent conductive film 41 in the X direction is almost constant.

To work out the metal grids in FIG. 3B, the grids of the original transparent conductive film are stretched in the Y direction, and then the grid of the transparent conductive film 51 is obtained by intercepting. The specific steps are similar to the steps to obtain the transparent conductive film 41 and thus not described here in details. Because these metal grids are obtained by stretching the original grids in the Y direction, distribution density of the grids is reduced in the Y direction and the area of the grids is increased. The slope of the grid metal lines is close to the Y direction, i.e. the distribution density of the metal lines contributing to the electrical conductivity in the Y direction is kept constant. Therefore the light transmittance of the transparent conductive film 51 is improved under the premise of keeping conductivity of the transparent conductive film 51 in the Y direction constant.

Finally, the above two transparent conductive films 41 and 51 are overlapped and because the grids of the two transparent conductive films 41 and 51 are both stretched, the light transmittance of the overlapped transparent conductive films are bound to be increased compared to the original transparent conductive films having the evenly distributed grids. Additionally, the transparent conductive films 41 and 51 respectively keep conductivity in the X or Y direction constant, the overall conductivity of the overlapped transparent conductive film module is kept constant. Therefore, the transparent conductive film module of the present disclosure solves the contradiction between light transmission and conductivity.

### EXAMPLE 2

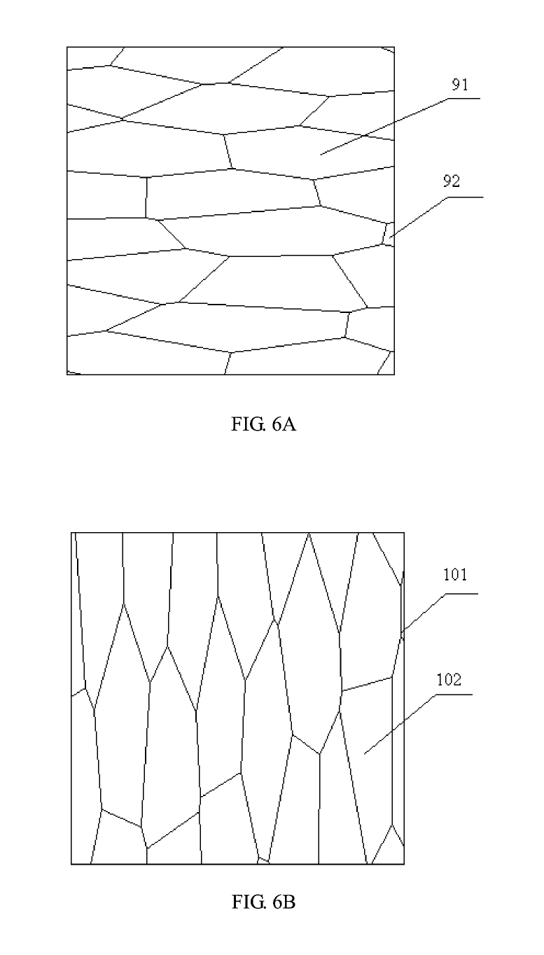

Referring to FIGS. 6A-6B, which are schematic views of the transparent conductive film module of the second embodiment of the present disclosure. As shown in FIGS. 6A-6B, the grids 92 of the transparent conductive film 91 are random polygon grids comprising metal lines, wherein the slope of the grid metal lines has a greater distribution probability density in a lateral direction than that in a vertical direction, i.e., the amount of the metal lines having a slope close to the X axis direction is greater than that of the metal line having a slope close to the Y axis direction. The visible light transmittance of the transparent conductive film 91 is greater than 88.6%. The grids 102 of the transparent conductive film 101 are also random polygon grids comprising metal lines, wherein the slope of the grid metal lines has a greater distribution probability density in a vertical direction than that in the lateral direction, i.e., the amount of the metal lines having a slope close to the Y axis direction is greater than that of the metal line having a slope close to the X axis direction. The visible light transmittance of the transparent conductive film 101 is greater than 88.6%. The visible light transmittance of the single-sided conductive transparent conductive films 91 and 101 in overlapping state is greater than 86.3%.

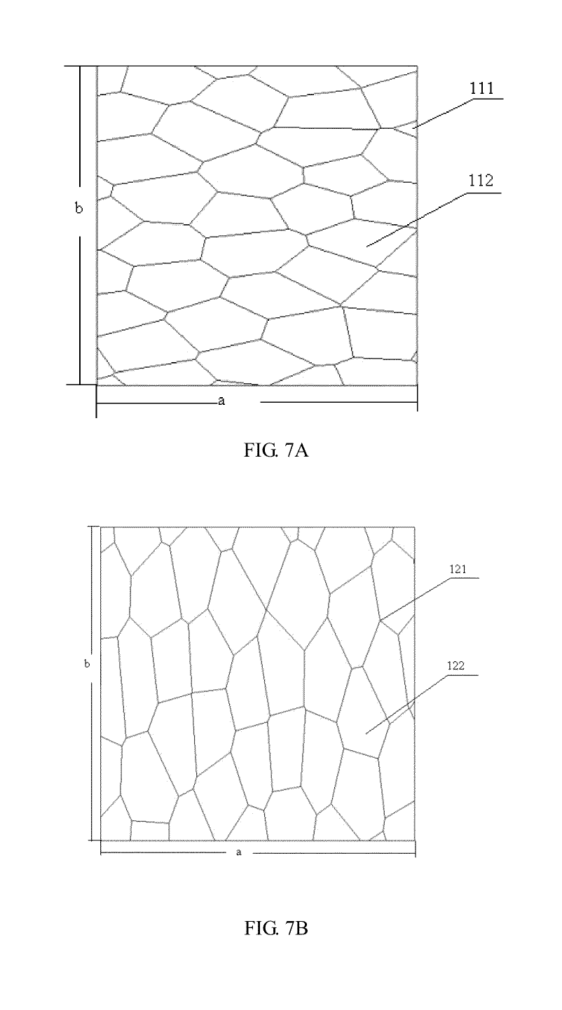

FIGS. 7A-7B show the design of the grids of the transparent conductive films in FIGS. 6A-6B, correspondingly. As shown in FIG. 7A, the grids of the transparent conductive film 111 are random polygon grids. The visible light transmittance of the transparent conductive film 111 is greater than 86.4%. The entire transparent conductive film 111 has a length defined as a and a width defined as b. On the basis of keeping the width b constant, the transparent conductive film 111 is stretched in the X direction to increase the length thereof to be 2a, and half of the grids are intercepting off in the X direction to get the grids 92 as shown in FIG. 6A. Since these grids, compared with the original grids, have reduced grid distribution density reduced in the X direction and increased grid area, the light transmittance is increased to 88.6%. Additionally, the slope of the grid metal lines is close to the X direction, i.e. the distribution density of the metal lines contributing to the electrical conductivity in the X direction is kept constant. Therefore, the electrical conductivity of the transparent conductive film 91 in the X direction is almost constant. A conductive film with improved visible light transmittance is obtained under the premise that the electrical conductivity of the obtained conductive film is kept constant. The grids of the transparent conductive film 121 shown in FIG. 7B are achieved with the similar method. The visible light transmittance of the transparent conductive film 121 is greater than 86.4%. The transparent conductive film 121 is stretched in the Y direction to double the width thereof And half of the grids are intercepted in the Y direction to increase the light transmittance of the transparent conductive film to 88.6%. Therefore a conductive film with improved visible light transmittance is obtained under the premise that the electrical conductivity thereof is kept constant. The two complementary transparent conductive films are applied in cell phone touch screen in overlapped state.

### EXAMPLE 3

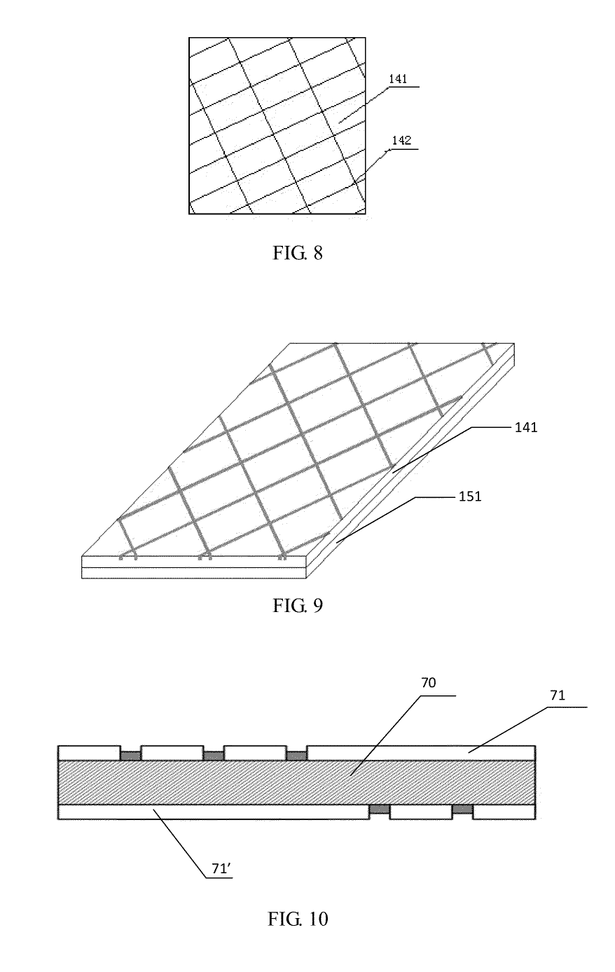

FIGS. 8 and 9 are schematic views of the transparent conductive film module of the third embodiment of the present disclosure. As shown in the FIGS, in this embodiment, the grids are rectangular grids consisting of metal lines. As shown in FIG. 8, the grids arranged on a surface of the conductive film 141 are rectangular grids 142, whose metal lines have different distribution density in the X and Y axes. The conductive film 141 has higher electrical conductivity in the X axis direction than in the Y axis direction. The slope of most of the metal lines of the grids 142 are ranged in the range of (−1, 1). The more metal lines having a slope within this slope range, the better the electrical conductivity of the conductive film in the X axis direction is. When the slope of most of the grid metal lines of the conductive film 151 is ranged in the range of (1, +∞) and (−∞, −1) (not shown), the electrical conductivity in the Y axis direction is much higher. The visible light transmittance of the conductive films 141 and 151 is 89.86%, the resistance in the corresponding X and Y axis directions are 58 ohms, respectively. The visible light transmittance of the two conductive films in overlapped state is 87.6%. Referring to FIG. 9, which is a stereoscopic view of part of the conductive film comprising oblique rectangular grids.

The method for manufacturing the transparent conductive film containing this rectangular grid is similar to that of examples 1 and 2, and will thus not be described here in detail. It should be pointed out that, to obtain rectangular grids, the original grids can be either evenly distributed rectangular grids or evenly distributed square grids.

### EXAMPLE 4

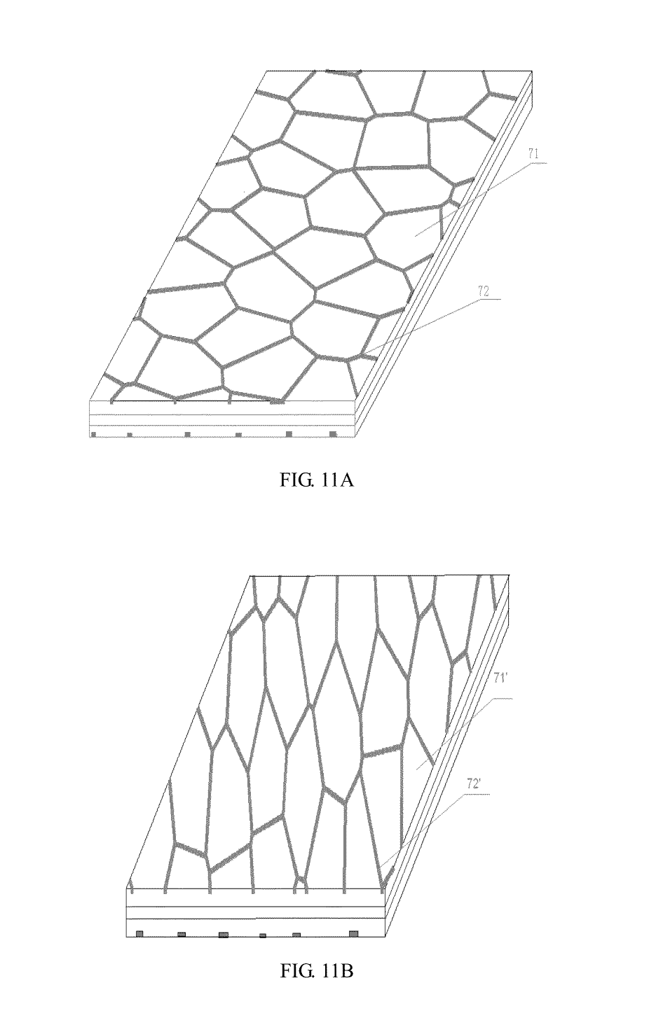

FIG. 10 is a schematic view of the transparent conductive film module of the fourth embodiment of the present disclosure. In this embodiment, the transparent conductive film module is not formed by simply overlapping two transparent conductive films, but by integrated two transparent conductive films on a single substrate. As shown in FIG. 10, this transparent conductive film module includes a middle substrate, a first transparent conductive film 71 located on the front side of the substrate, and a second transparent conductive film 71′ located on the back side of the substrate. The first transparent conductive film 71 and the second transparent conductive film 71′ define grooves in the thermoplastic polymer layer through embossing, followed by filling the groove with the conductive material to form transparent conductive films. Finally, the transparent conductive films are attached to the front and back sides of the substrate 70 to form this transparent conductive film module.

As shown in FIG. 11A, the grids 72 of the transparent conductive film 71 are random polygon random grids, wherein the slope of the metal lines of the grids 72 of the transparent conductive film 71 has greater probability density in a lateral direction than that in a vertical direction, that is, the amount of the metal lines having a slope close to the X axis direction is greater than that of the metal lines having a slope close to the Y axis direction. The visible light transmittance of the transparent conductive film 71 is greater than 86.4%. As shown in FIG. 11B, the grids 72′ of the transparent conductive film 71′ are also random polygon grids, wherein the slope of the metal lines of the grid 72′ of the transparent conductive film 71′ has greater probability density in a vertical direction than that in a lateral direction, that is, the amount of the metal lines having a slope close to Y axis direction is greater than that of the metal lines having a slope close to the X axis direction. The visible light transmittance of the transparent conductive film 71′ is greater than 86.4%.The transparent conductive films 71 and 71′ share one and the same substrate 70, and are located on the front side and back sides of this substrate 70, respectively. The visible light transmittance of the transparent conductive film module formed by combination of the conductive films 71 and 71′ is greater than 84.1%. The resistance of the conductive film module in the X or Y direction is 102 ohms. The transmittance and resistance involved in this example are measured under the condition that the width of the metal lines is 2.5 μm.

The grids in this embodiment can also be replaced by the rhombus as Example 1 and the rectangle as Example 3. The structure of the conductive film module of Example 4 can likely be applied to the structure of any conductive film in Examples 1-3.

The substrate of the patterned transparent conductive film for the cell phone touchscreen in the above examples is not limited to the aforementioned materials, and may also be glass, quartz, polymethyl methacrylate (PMMA), polycarbonate (PC) or other suitable material. The conductive material mentioned in the present disclosure is not limited to silver, and may also be graphite, a macromolecular conductive material, etc.

In summary, in the present disclosure, through stretching and intercepting the grids of the first transparent conductive film and the second transparent conductive film of the transparent conductive film module in the X and Y directions, respectively, the area of the grids, i.e. the light transmitting region, is increased, thus the light transmittance of the entire transparent conductive film is increased. On the other hand, since stretching and intercepting in a single direction can keep the probability density of the metal lines having a slope close to this direction constant, the electrical conductivity of this transparent conductive film in this direction can substantially be kept constant.

Although the invention has been described in language specific to structural features and/or methodological acts, it is to be understood that the invention defined in the appended claims is not necessarily limited to the specific features or acts described. Rather, the specific features and acts are disclosed as sample forms of implementing the claimed invention.

1. A transparent conductive film module, comprising:
a first transparent conductive film; and
a second transparent conductive film, which are transparent conductive films including metal embedded grids having grid-like grooves evenly filled with conductive material, wherein a slope of the grid metal lines in the first transparent conductive film has a greater probability density in a lateral direction than in a vertical direction; a slope of the grid metal lines in the second transparent conductive film has a greater probability density in the vertical direction than in a the lateral direction.

2. The transparent conductive film according to claim 1, wherein the probability density of the grid metal lines of the first transparent conductive film with slope ranged in a range of (−1, 1) is greater than that of the grid metal lines with the slope ranged in other ranges; the probability density of the grid metal lines of the second transparent conductive film with slope ranged in ranges of (−∞, −1) and (1, +∞) is greater than that of the grid metal lines with the slope ranged in other ranges.

3. The transparent conductive film according to claim 1, wherein the first transparent conductive film is laminated to the second transparent conductive film up and down.

4. The transparent conductive film according to claim 1, wherein the first transparent conductive film and the second transparent conductive film share one substrate, and the first transparent conductive film and the second transparent conductive film are attached to front and back sides of the substrate, respectively.

5. A transparent conductive film, comprising:
metal embedded grids formed by filling grid-like grooves defined therein with conductive material, wherein a slope of the grid metal lines in the transparent conductive film has greater probability density in one of two orthogonal directions.
